(19) United States
(12) Patent Application Publication
(10) Pub. No.: US 2011/0267113 A1
(43) Pub. Date: Nov. 3, 2011

(54) FREQUENCY MULTIPLIER

(75) Inventors: Roi Carmon, Nesher (IL); Danny Elad, Liman (IL); Benny Sheinman, Haifa (IL)

(73) Assignee: International Business Machines Corporation, Armonk, NY (US)

(21) Appl. No.: 12/768,768

(22) Filed: Apr. 28, 2010

(51) Int. Cl. H03B 19/00

(52) U.S. Cl. 327/122

(57) ABSTRACT

A multiplier circuit, including: a transistor with gate, source and drain connections adapted to accept an input signal by the transistor gate; a reference voltage source providing a DC reference voltage to the transistor drain; an inductor connected between the drain and the reference voltage source; a resistor connected in parallel to the inductor between the transistor drain and the reference voltage source; a current source providing a DC current to the transistor source; two capacitors forming a voltage divider, with the first capacitor connecting between the gate and the source and the second capacitor connecting between the source and the ground in parallel to the current source; and wherein the multiplier circuit is adapted to accept an input signal and provide as output an amplified current signal with a frequency that is double that of the input signal.

### FIELD OF THE INVENTION

The present invention relates generally to an electronic frequency multiplier and more specifically to a circuit design that provides a current output with a frequency that is double the input frequency.

### BACKGROUND

In many electronic applications use is made of frequency multipliers. Some examples of such applications are communication front end systems and radars. Typically these applications use signals that are multiples of a basic input frequency to serve as local oscillators for implementing down/up converting mixers or transmitting at different frequencies that are multiples of the base frequency.

The traditional methods to implement frequency multipliers are based on the non linear behavior of an active input device. Typically, the input signal is partially cut due to instantaneous cutoff or saturation of the active device to provide an amended output signal with higher multiples of the input signal harmonic. A signal with the required harmonic can then be provided by combining cutoff signals. Another approach is based on a passive circuit with the use of Schottky diodes. The harmonic products appear as a result of the diodes non linearity.

The main drawbacks of the conventional approaches are due to the complexity of the circuits for implementing the frequency multipliers (especially inductors), which then increase the dimensions of such implementations making them less feasible to implement as small scale integrated circuits such as CMOS circuits. Additionally, the conventional approaches tend to suffer from low power efficiency.

### SUMMARY

One exemplary embodiment of the disclosed subject matter is a multiplier circuit, comprising: a transistor having gate, source and drain connections, wherein the transistor is adapted to accept an input signal through the gate connection; a reference voltage source providing a DC reference voltage to the drain connection of the transistor; an inductor connected between the drain connection and the reference voltage source; a resistor connected in parallel to the inductor between the drain connection and the reference voltage source; a current source providing a DC current to the transistor source; two capacitors forming a voltage divider, with the first capacitor connecting between the gate connection and the source connection and the second capacitor being connected to ground in parallel to the current source; and wherein the multiplier circuit is adapted to accept an input signal and provide as output a current signal with a frequency that is double that of the input signal.

Another exemplary embodiment of the disclosed subject matter is a method for producing a multiplier circuit, the method comprising: selecting a transistor having a voltage threshold; the transistor having a gate, source and drain connections; selecting two capacitors having a capacitance ratio; selecting a resistor having a resistance value; selecting a DC current source; selecting a DC voltage source; producing the multiplier circuit by: connecting the transistor to the two capacitors using the gate connection and the source connection; connecting the source connection to the DC current source; and connecting the drain connection to the resistor.

### BRIEF DESCRIPTION OF THE DRAWINGS

The present invention will be understood and better appreciated from the following detailed description taken in conjunction with the drawings. Identical structures, elements or parts, which appear in more than one figure, are generally labeled with the same or similar number in all the figures in which they appear, wherein:

FIG. 1 is a schematic illustration of a multiplier circuit, according to an exemplary embodiment of the invention;

FIG. 2 is a schematic graph of the output current versus the transistor voltage during a single cycle using a multiplier circuit, according to an exemplary embodiment of the disclosed subject matter;

FIG. 3 is a schematic graph of the input voltage, transistor voltage and output current as a function of time over a single cycle, according to an exemplary embodiment of the disclosed subject matter;

FIG. 4 is a schematic graph of the output power spectra relative to the input power spectra during use of a multiplier circuit, according to an exemplary embodiment of the disclosed subject matter;

FIG. 5 is a schematic graph of the voltages on a transistor in a multiplier circuit, according to an exemplary embodiment of the disclosed subject matter; and

FIG. 6 is schematic graph illustrating the power output of the first harmony and the second harmony versus the input frequency, according to an exemplary embodiment of the disclosed subject matter.

### DETAILED DESCRIPTION

An aspect of an embodiment of the disclosed subject matter, relates to a system and method for accepting an input signal and producing as output a signal with a current frequency that is double the frequency of the input signal. The system includes a multiplier circuit that is comprised from a single transistor including a gate connection, a source connection and a drain connection. In an exemplary embodiment of the disclosed subject matter, the gate connection serves as the input and it is further connected to the source connection over a voltage divider made up from two capacitors, so that a derivative of the input signal is provided to the source to control the output of the transistor.

In an exemplary embodiment of the disclosed subject matter, the drain connection is provided a DC reference voltage over a resistor and an inductor in parallel to each other. The source may be connected by a first capacitor to the gate and provided current from a DC current source that is in parallel to a second capacitor.

In an exemplary embodiment of the disclosed subject matter, the values of the DC reference voltage, DC current source, capacitors, resistor and inductor are selected to cause the transistor to double the frequency of the current of the input signal for a specific signal range having a specific voltage range and frequency range.

Optionally, the circuit may be designed to keep the transistor in the triode region during approximately half the period of the input signal and keep the transistor in the saturation region for the other half of the period of the input signal.

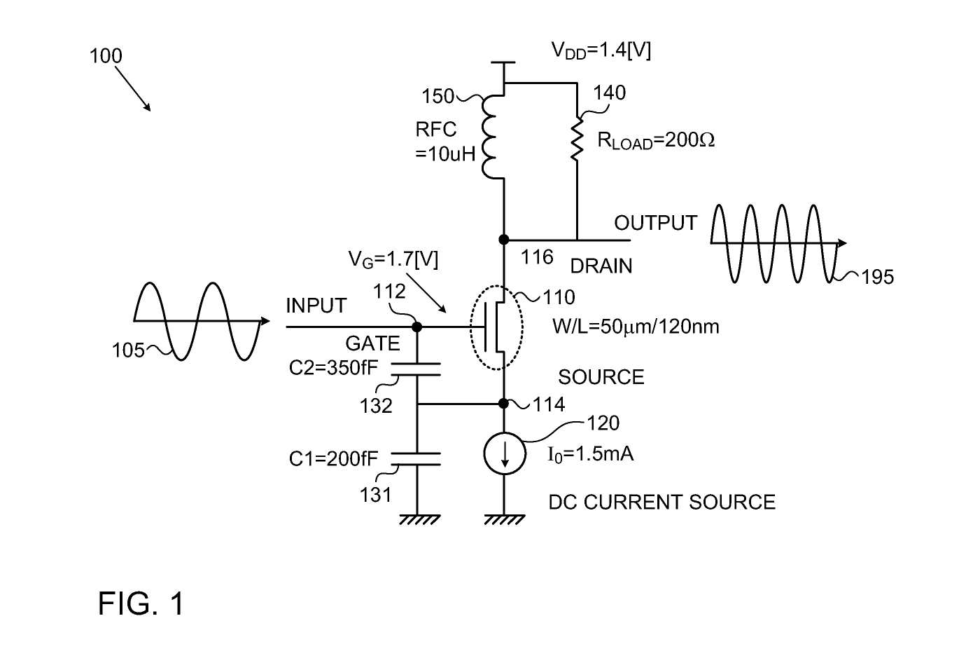

FIG. 1 is a schematic illustration of a multiplier circuit 100, according to an exemplary embodiment of the disclosed subject matter. In an exemplary embodiment of the disclosed subject matter, circuit 100 uses a transistor 110 with a gate 112, a source 114 and a drain 116. Optionally, transistor 110 may accept an input signal 105 and generates a current output signal 195 that is a second harmonic of input signal 105. This is achieved by placing constraints on the source and drain of the transistor and controlling the source with the input signal, so that circuit 100 produces as output a signal wherein the output current reaches a maximum and minimum twice for every cycle of the input signal. In an exemplary embodiment of the disclosed subject matter, transistor 110 is a MOS, NMOS, PMOS, DMOS or CMOS transistor. Alternatively, other types of transistors may be used, such as pHEMT FET or HBT.

In an exemplary embodiment of the disclosed subject matter, input signal 105 is provided to gate 112 of transistor 110. Optionally, two capacitors (C1 131 and C2 132) forming a voltage divider may be used to control the signal on the source connection of transistor 110. Capacitor C2 132 may connect between gate 112 and source 114 of transistor 110. In an exemplary embodiment of the disclosed subject matter, source 114 is also provided current from a DC current source 120 placed in parallel to capacitor C1 131 to control the status of transistor 110. Optionally, capacitors C1 131 and C2 132 may be placed in a Colppits configuration as used in oscillator circuits to control the signal at source 114 of transistor 110. In an exemplary embodiment of the disclosed subject matter, drain 116 of transistor 110 may be loaded with a load RL 140 and an RF choke (e.g. an inductor such as a coil) RFC 150. The output of multiplier circuit 100 is provided from drain 116. In some exemplary embodiments, multiplier circuit 100 can be easily implemented in integrated circuits since it is comprised from simple basic elements and only requires a single inductor.

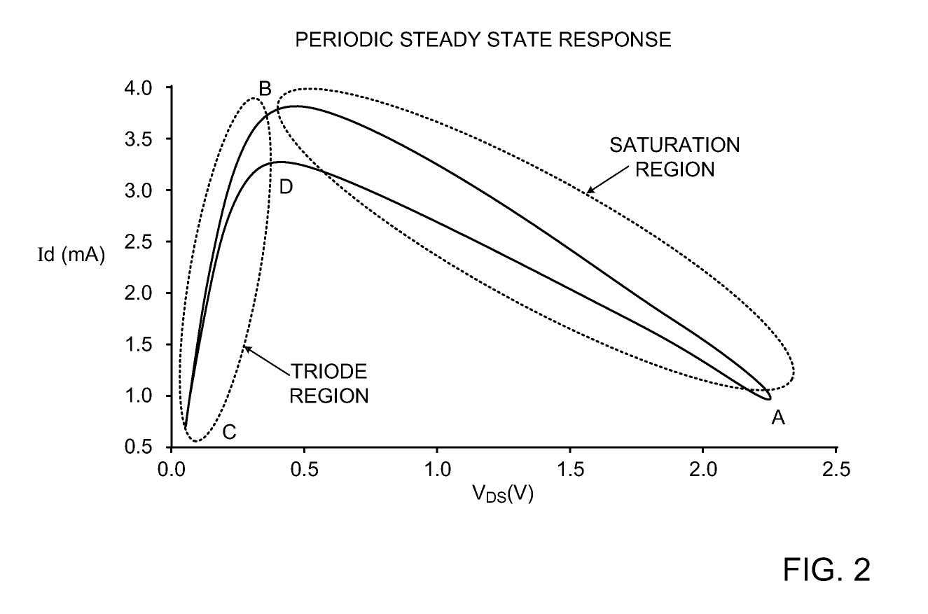

FIG. 2 is a schematic graph of the output current I_{d} versus the transistor voltage V_{ds} (between the drain and the source) during a single cycle using multiplier circuit 100, according to an exemplary embodiment of the disclosed subject matter. Optionally, the output current I_{d} may be designed to pass through 4 extreme points (A, B, C, D) during each cycle of input signal 105. In an exemplary embodiment of the disclosed subject matter, current I_{d} may reach a maximum at points B and D and may reach a minimum at points A and C.

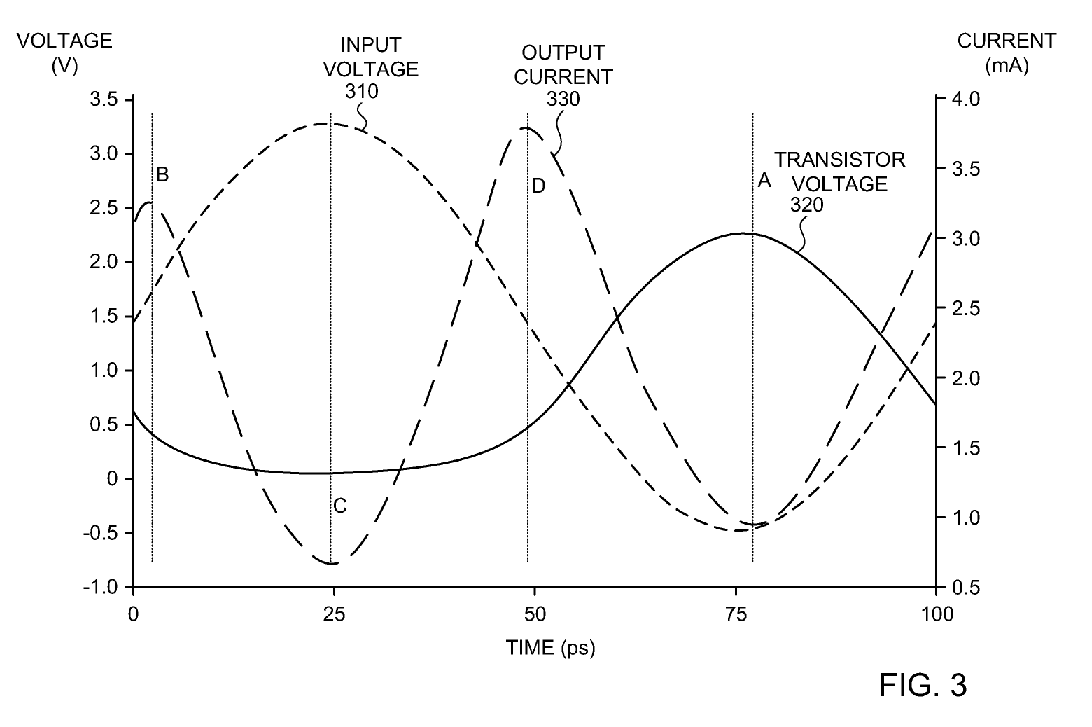

FIG. 3 is a schematic graph of the input voltage 310, transistor voltage 320 (V_{ds}) and output current 330 as a function of time over a single cycle, according to an exemplary embodiment of the disclosed subject matter. In an exemplary embodiment of the disclosed subject matter, input voltage 310 may represent the voltage of input signal 105 of FIG. 1 with a fundamental frequency F, and a cycle of period T=1/F. Optionally, at point A input voltage 310 is at a minimum. In some exemplary embodiments, the voltage between gate 112 and source 114 of FIG. 1 may be close to zero. As a result transistor 110 may be momentarily in the cutoff region of operation. In the cutoff region the output current 330 is low and the transistor voltage 320 is high. In circuit 100 the total current over capacitors C1 131 and C2 132 is equal to the input current. As the input voltage 310 increases, toward point B, the voltage between gate 112 and source 114 increases, causing transistor 110 to leave the cutoff region (in case it was in the cutoff region in point A) and the output current 330 to rise. As the transistor voltage 320 decreases, the output current 330 rises, the output current 330 is applied to RL 140 and RFC 150 producing an opposing potential at drain 116. At point B the output current 330 is at a maximum and the transistor voltage 320 is decreasing toward a minimum at point C. At point B the transistor 110 is in the triode region of operation. As the transistor voltage 320 advances toward point C the transistor voltage 320 may decrease to zero and the output current 330 may also decrease toward zero. The transistor may enter a deep-ohmic (saturated) region of operation, also referred to as a saturation region. In the saturation region the total currents of C1 131 and C2 132 may be equal to the input current forcing the output current 330 of transistor 110 to be zero. As the input voltage 310 begins to decrease moving from point C to point D, the voltage applied to source 114 may decrease and the output current 330 may begin to rise. Likewise the total current over capacitors C1 131 and C2 132 begins to decrease and is lower than the input current. Point C and point D are both arrived at when the device is in the triode region of operation. From point D back to point A the input voltage 310 continues to decrease, the transistor enters the saturation region of operation, the transistor voltage 320 increases while the output current 330 decreases. In some exemplary embodiments, the transistor may be in the saturation region between points D, A and B, and in the triode region between points B, C and D, without entering the cutoff region, as is exemplified in FIG. 2.

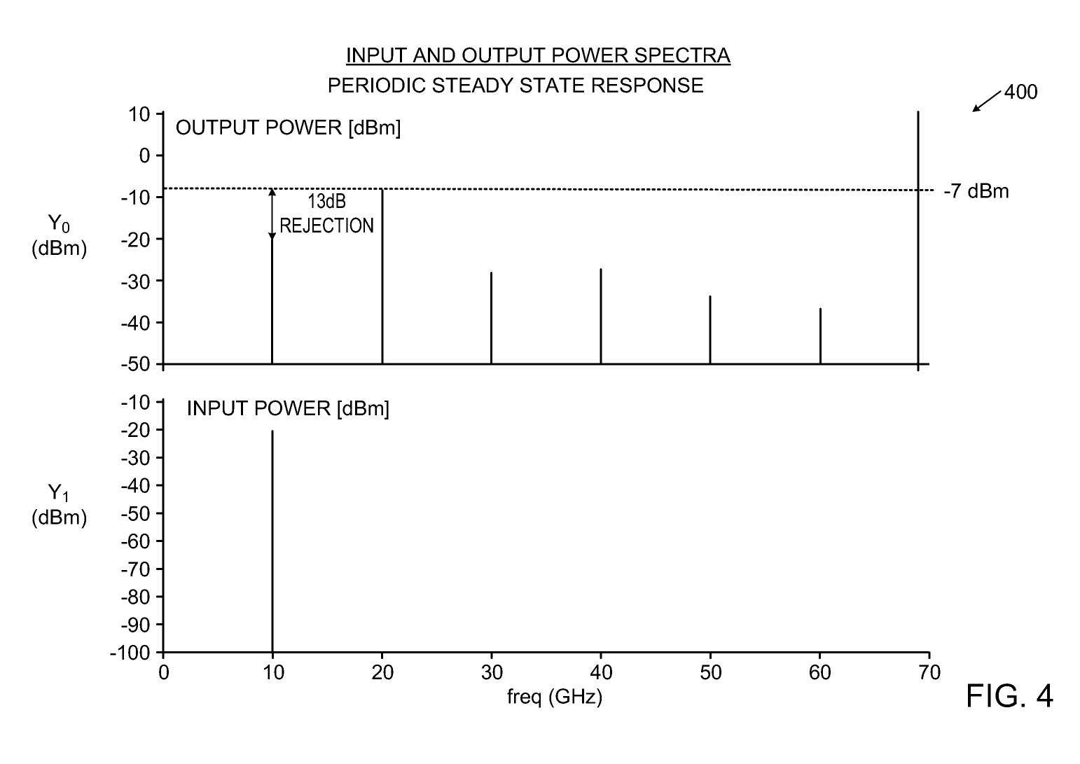

FIG. 4 is a schematic graph 400 of the output power spectra relative to the input power spectra during use of a multiplier circuit 100, according to an exemplary embodiment of the disclosed subject matter. In an exemplary embodiment of the disclosed subject matter, an ideal sinusoidal signal for example with a frequency of 10 GHz and power level (in a logarithmic scale) of −20 dbm is provided as input to multiplier circuit 100. Optionally, the output power from multiplier circuit 100 will have a second harmonic power level of −7 dbm (at 20 GHz) and much weaker power levels at all other frequencies of the spectra, for example the next highest level being −20 dbm at 10 GHz, a difference of 13 dbm (in the logarithmic scale), exemplifying an acceptable rejection level.

In some exemplary embodiments, the input signal may be a non-ideal signal and have negligible output power at other harmonics different from the fundamental harmonic. The output signal may also be a non-ideal signal, as is described in the schematic graph 400, having negligible output power at other harmonics different from the second harmonic.

In an exemplary embodiment of the disclosed subject matter, multiplier circuit 100 is designed to function for a specific voltage range, wherein the range is determined by applying certain constraints to the inputs of a specific transistor having a given threshold voltage. Optionally, the constraints are controlled by selecting the Vdd voltage, selecting current I₀ provided by DC current source 120, selecting the values of the capacitors C1 131 and C2 132, and selecting the values of RFC 150 and RL 140.

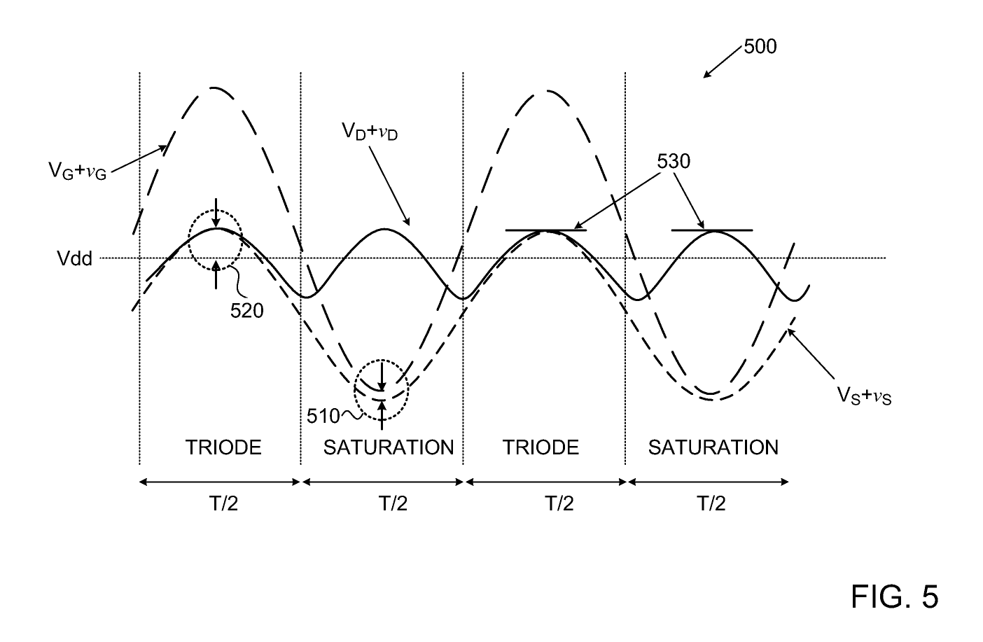

FIG. 5 is a schematic graph of the voltages on transistor 110 in multiplier circuit 100, according to an exemplary embodiment of the disclosed subject matter. In FIG. 5, V_{g} represents the DC voltage on the gate of transistor 110 and v_{g} represents the AC voltage on the gate of transistor 110. Likewise V_{d}, V_{d} are the DC and AC voltages on the drain and Vₛ, vₛ are the DC and AC voltages on the source.

In the Triode region for the first half of the input signal:

V_{g}+v_{g}−V_{threshold}>V_{d}+v_{d};
Whereas in the saturation region:

V_{g}+v_{g}−V_{threshold}<V_{d}+V_{d}.

In some exemplary embodiments, to avoid entering the transistor's cutoff region it may be required that:

(V_{g}+v_{g})−(Vₛ+vₛ)>V_{threshold};
Since vₛ=(C2/(C1+C2)) v_{g}; one can deduce that:

(V_{g}−Vₛ)+v_{g}−vₛ>(V_{g}−Vₛ)−|v_{g}|(C2/(C1+C2))>V_{threshold};

So that the amplitude of the AC part of the input signal conforms to (see 510 in FIG. 5):

|v_{g}|>|(V_{g}−Vₛ)−V_{threshold}|(C1+C2)/C1)|

In some exemplary embodiments, Vdd<Vₛ+|vₛ| (the maximum voltage on the source—the DC voltage+maximum amplitude of the AC voltage (see 520 in FIG. 5)). This may provides a constraint over Vdd:

Vdd<Vₛ+|v_{g}|(C2/(C1+C2)).

In some exemplary embodiments, to improve the efficiency of multiplier circuit 100, RL 140 may be tuned so that the amplitude of v_{d} during the triode region will be about equal to its value during the saturation region (see 530 in FIG. 5):

Vdd+v_{d}≈Vdd+RL I₀=Vₛ+|v_{g}|(C2/(C1+C2))

So that:

RL≈(Vₛ+|v_{g}|(C2/(C1+C2))−Vdd)/I₀

In some exemplary embodiments, once the above variables are selected, multiplier circuit 100 will be available to provide duplication of the frequency of the current output for a specific range of input signals having a specific voltage range and specific frequency range based on the selected variables.

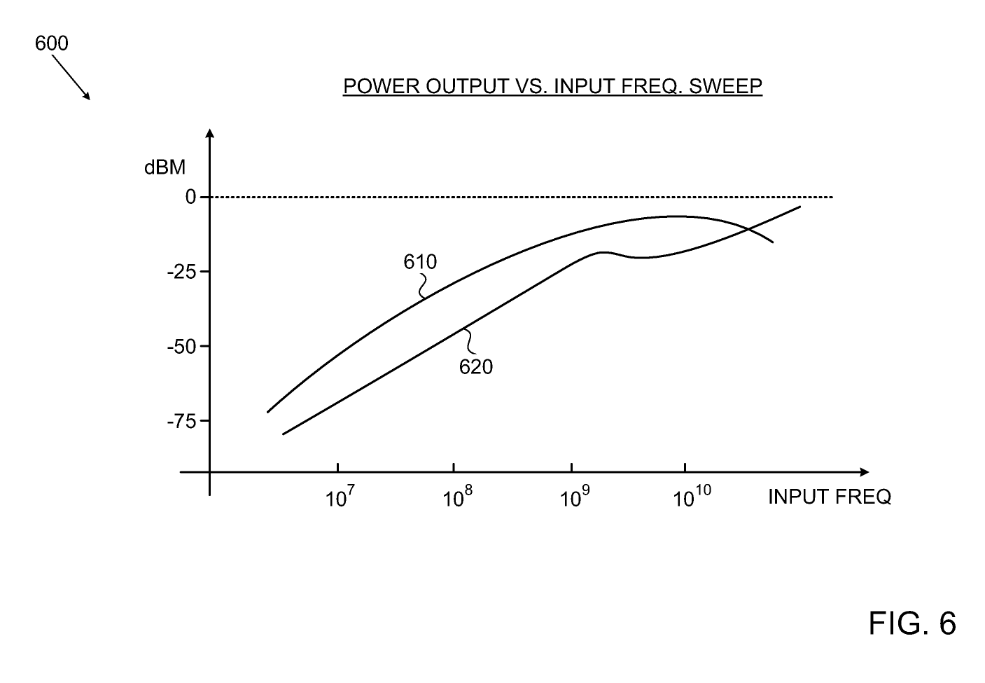

FIG. 6 is schematic graph 600 illustrating the power output of the first harmony 620 and the second harmony 610 versus the input frequency, according to an exemplary embodiment of the disclosed subject matter. Optionally, in a specific range of frequencies (e.g. between 1 GHz to 50 Ghz) the second harmony 610 is significantly stronger than the first harmony 620 and the power output is not too low (e.g. greater than −25 dBm in a logarithmic scale) so that multiplier circuit 100 provides an effective result.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A multiplier circuit, comprising:
a transistor having gate, source and drain connections, wherein said transistor is adapted to accept an input signal through said gate connection;
a reference voltage source providing a DC reference voltage to said drain connection of said transistor;
an inductor connected between said drain connection and the reference voltage source;
a resistor connected in parallel to said inductor between said drain connection and the reference voltage source;
a current source providing a DC current to the transistor source;
two capacitors forming a voltage divider, with the first capacitor connecting between said gate connection and said source connection and the second capacitor being connected to ground in parallel to the current source; and
wherein said multiplier circuit is adapted to accept an input signal and provide as output a current signal with a frequency that is double that of the input signal.

2. The multiplier circuit according to claim 1, adapted to maintain said transistor in a triode region during about first half of the period of the input signal and in a saturation region during second other half of the period of the input signal.

3. The multiplier circuit according to claim 1, wherein a maximum voltage on said source connection during a cycle of the input signal is greater than the reference voltage.

4. The multiplier circuit according to claim 1, wherein said resistor is configured to have a resistance value such that an amplitude of a voltage on said drain connection is about the same in a triode region as in a saturation region.

5. The multiplier circuit according to claim 1, wherein a reference voltage (Vdd) of the reference voltage source is less than a DC voltage on the source connection combined with an amplitude of an alternating voltage on the gate connection multiplied by a value of the capacitor (C2) between the gate connection and the source connection and a combined capacitance of the two capacitors (|v_{g}|(C2/(C1+C2))).

6. The multiplier circuit according to claim 1, wherein said two capacitors are configured to have a ratio wherein an alternating voltage of the input signal is greater than a difference between a DC voltage on the gate connection minus a DC voltage on the source connection and a DC inherent threshold voltage of the transistor times a ratio of a combined capacitance of the two capacitors (C1+C2) and a capacitance of a first capacitor of the two capacitors (C1) in parallel to the DC current (|v_{g}|>|(V_{g}−Vₛ)−V_{threshold}|(C1+C2)/C1)|).

7. The multiplier circuit according to claim 1, wherein said inductor is an RF Choke.

8. The multiplier circuit according to claim 7, wherein said RF Choke is a coil.

9. A method of providing a multiplied current frequency, the method comprising:
supplying an input signal to a multiplier circuit, the input signal having a first current frequency; wherein the multiplier circuit comprises:
a transistor with gate, source and drain connections adapted to accept an input signal by the gate connection;
a reference voltage source providing a DC reference voltage to the drain connection;
an inductor connected between the drain connection and the reference voltage source;
a resistor connected in parallel to the inductor between the drain connection and the reference voltage source;
a current source providing a DC current to the source connection;
two capacitors forming a voltage divider, with the first capacitor connecting between the gate connection and the source connection and the second capacitor connecting between the source connection and ground in parallel to the current source; and
wherein said supplying the input signal comprises supplying the input signal to the gate connection of the transistor;
the method further comprises the multiplier circuit transforming the input signal to an output signal having a second current frequency; wherein the second current frequency is about double the first current frequency.

10. The method of claim 9, wherein the inductor is an RF Choke.

11. A method for producing a multiplier circuit, the method comprising:
selecting a transistor having a voltage threshold; the transistor having a gate, source and drain connections;
selecting two capacitors having a capacitance ratio;
selecting a resistor having a resistance value;
selecting a DC current source;
selecting a DC voltage source;
producing the multiplier circuit by:
connecting the transistor to the two capacitors using the gate connection and the source connection;
connecting the source connection to the DC current source; and
connecting the drain connection to the resistor; and
wherein the multiplier circuit is adapted to accept an input signal and provide as output a current signal with a frequency that is double that of the input signal.

12. The method of claim 11, wherein the inductor is an RF Choke.

13. The method of claim 12, wherein said selecting the transistor, selecting the two capacitors, selecting the resistor, selecting the DC current source, selecting the DC voltage source and selecting the RF choke is performed so that they comply with a constraint selected from the group consisting of:
Vdd<Vₛ+|v_{g}|(C2/(C1+C2)); and

|v_{g}|>|(V_{g}−Vₛ)−V_{threshold}|(C1+C2)/C1)|.

14. The method of claim 13, wherein said selecting the transistor, selecting the two capacitors, selecting the resistor, selecting the DC current source, selecting the DC voltage source and selecting the RF choke is performed to comply with all constraints of the group.

15. The method of claim 11, wherein said selecting the resistor comprises selecting a resistor so that the resistance value is about equal to (Vₛ+|v_{g}|(C2/(C1+C2))−Vdd)/I₀.
